(19) United States
(12) Patent Application Publication
(10) Pub. No.: US 2025/0008794 A1
(43) Pub. Date: Jan. 2, 2025

(54) DISPLAY SUBSTRATE AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Bangqing XIAO, Beijing (CN); Meng LI, Beijing (CN); Benlian WANG, Beijing (CN); Qiwei WANG, Beijing (CN); Hai ZHENG, Beijing (CN)

(21) Appl. No.: 18/704,476

(22) PCT Filed: May 11, 2023
(86) PCT No.: PCT/CN2023/093443

§ 371 Date: Apr. 25, 2024

(30) Foreign Application Priority Data
Jun. 20, 2022 (CN) 202210699692.8

(51) Int. Cl. H10K 59/131; H10K 59/35; H10K 59/90

(52) U.S. Cl. CPC H10K 59/131; H10K 59/353; H10K 59/90

(57) ABSTRACT

A display substrate, comprising a substrate, a circuit structure layer, a light-emitting structure layer and multiple conductive layers. The circuit structure layer is arranged on one side of the substrate and comprises multiple first pixel circuits located in the second display region. The light-emitting structure layer is arranged on the side of the circuit structure layer away from the substrate, and comprises multiple first light-emitting elements in the first display region. The multiple conductive layers are arranged between the circuit structure layer and the light-emitting structure layer, and comprise multiple conductive wires. The multiple conductive wires of the at least one conductive layer comprise multiple first conductive wires and multiple second conductive wires. The first conductive wires extend in a first direction, and each of the second conductive wires at least comprises first parts extending in the first direction and second parts extending in a second direction.

### CROSS-REFERENCE TO RELATED APPLICATIONS

The present application is a U.S. National Phase Entry of International Application PCT/CN2023/093443 having an international filing date of May 11, 2023, which claims priority to Chinese Patent Application No. 202210699692.8, filed to the CNIPA on Jun. 20, 2022 and entitled “Display Substrate and Display Device”, the contents of which should be construed as being incorporated herein by reference.

### TECHNICAL FIELD

The present disclosure relates to, but is not limited to, the field of display technologies, in particular to a display substrate and a display device.

### BACKGROUND

Organic Light Emitting Diodes (OLEDs) and Quantum-dot Light Emitting Diodes (QLEDs) are active light emitting display devices and have advantages of self-illumination, wide viewing angle, high contrast ratio, low power consumption, an very high reaction speed, lightness and thinness, flexibility, and low cost, etc. An under-display camera technology is a novel technology proposed for increasing a screen-to-body ratio of a display device.

### SUMMARY

The following is a summary of subject matter described herein in detail. This summary is not intended to limit the protection scope of claims.

Embodiments of the present disclosure provide a display substrate and a display device.

In one aspect, a display substrate is provided in an embodiment of the present disclosure, which includes a base substrate, a circuit structure layer, a light emitting structure layer and a plurality of conductive layers. The base substrate includes a display area including a first display region and a second display region which are not overlapped with each other. The second display region may be located on at least one side of the first display region. The circuit structure layer is located on a side of the base substrate, and includes a plurality of first pixel circuits located in the second display region. The light emitting structure layer is located on a side of the circuit structure layer away from the base substrate, and includes a plurality of first display units located in the first display region, wherein at least one first display unit includes a plurality of first light emitting elements emitting light in different colors; A plurality of conductive layers are located between the circuit structure layer and the light emitting structure layer, and include a plurality of conductive lines. At least one first pixel circuit of the plurality of first pixel circuits is electrically connected to at least one first light emitting element of a plurality of first light emitting elements through at least one conductive line. The plurality of conductive lines of at least one conductive layer includes a plurality of first conductive lines and a plurality of second conductive lines. The first conductive lines extend along a first direction, and the second conductive lines at least includes first portions extending along the first direction and second portions extending along the second direction. In the second direction, first portions of the plurality of second conductive lines and the plurality of first conductive lines are alternately disposed. The first direction intersects with the second direction.

In some exemplary implementations, a plurality of first display units arranged along the first direction are one row of first display units; in a direction from a center to an edge of the first display region along the second direction, quantities of the first conductive lines located in a same conductive layer to which a plurality of rows of first display units in the first display region are electrically connected are gradually reduced; the first portions of the second conductive lines in the conductive layer are disposed at positions left vacant due to the reduced quantities of the first conductive lines.

In some exemplary implementations, quantities of first display units in at least two adjacent rows of first display units are different in the second direction.

In some exemplary implementations, in a row of first display units, when adjacent first light emitting elements are electrically connected to different conductive lines located in the same conductive layer, the conductive lines electrically connected to the adjacent first light emitting elements are located on opposite sides of anode connection electrodes electrically connected to the first light emitting elements of the row of first display units in the second direction.

In some exemplary implementations, a length of a second portion of the second conductive line along the second direction is greater than a length of one first display unit along the second direction.

In some exemplary implementations, the at least one first display unit includes a first light emitting element that emits light in a first color, a first light emitting element that emits light in a second color, and two first light emitting elements that emit light in a third color.

In some exemplary implementations, the plurality of conductive layers include a first conductive layer and a second conductive layer provided sequentially along a direction away from the base substrate.

In some exemplary implementations, the first conductive layer includes a plurality of first conductive lines and a plurality of second conductive lines, and the second conductive layer includes a plurality of first conductive lines.

In some exemplary implementations, the first display region includes N rows of first display units arranged from the center to the edge of the first display region along the second direction, wherein a quantity of first display units included in an i-th row of first display units is greater than or equal to a quantity of first display units included in an (i+1)-th row of first display units, wherein i is an integer greater than 0 and less than N.

In some exemplary implementations, a quantity of first conductive lines in the second conductive layer to which the i-th row of first display units are electrically connected is the same as a quantity of first conductive lines in the second conductive layer to which the (i+1)-th row of first display units are electrically connected. A quantity of first conductive lines in the first conductive layer to which the i-th row of first display units are electrically connected is greater than or equal to a quantity of first conductive lines in the first conductive layer to which the (i+1)-th row of first display units are electrically connected.

In some exemplary implementations, the i-th row of first display units are electrically connected to second conductive lines in the first conductive layer, first portions of the second conductive lines to which the i-th row of first display units are electrically connected are adjacent to first conductive lines in the first conductive layer to which a j-th row of first display units are electrically connected, and j is an integer greater than i and less than or equal to N.

In some exemplary implementations, in the i-th row of first display units, first light emitting elements close to the center of the first display region are electrically connected to first pixel circuits through second conductive lines located in the first conductive layer, and first light emitting elements close to the edge of the first display region are electrically connected to first pixel circuits through first conductive lines located in the first conductive layer. In the j-th row of first display units, first light emitting elements close to the center of the first display region are electrically connected to first pixel circuits through first conductive lines located in the second conductive layer, and first light emitting elements close to the edge of the first display region are electrically connected to first pixel circuits through first conductive lines located in the first conductive layer.

In some exemplary implementations, the circuit structure layer further includes a plurality of second pixel circuits located in the second display region. The light emitting structure layer further includes a plurality of second light emitting elements located in the second display region. At least one second pixel circuit of the plurality of second pixel circuits is electrically connected to at least one second light emitting element of the plurality of second light emitting elements, and the at least one second pixel circuit is configured to drive the at least one second light emitting element to emit light.

In another aspect, a display device is provided in an embodiment of the present disclosure, which includes the display substrate described above.

In some exemplary implementations, the display device further includes a photosensitive sensor located on a side of a non-display surface of the display substrate, wherein an orthographic projection of the photosensitive sensor on the display substrate is at least partially overlapped with the first display region of the display substrate.

Other aspects of the present disclosure may be comprehended after the drawings and the detailed descriptions are read and understood.

### BRIEF DESCRIPTION OF DRAWINGS

Accompanying drawings are used for providing further understanding of technical solutions of the present disclosure, constitute a part of the specification, and are used for explaining the technical solutions of the present disclosure together with embodiments of the present disclosure, but do not constitute limitations on the technical solutions of the present disclosure. Shapes and sizes of one or more components in the drawings do not reflect actual scales, and are only intended to schematically describe contents of the present disclosure.

FIG. 1 is a schematic diagram of a display substrate according to at least one embodiment of the present disclosure.

FIG. 2 is a partial schematic view of a display substrate according to at least one embodiment of the present disclosure.

FIG. 3 is a schematic diagram of a first conductive layer in FIG. 2.

FIG. 4 is a partial schematic sectional view of a display substrate according to at least one embodiment of the present disclosure.

FIG. 5 is a schematic diagram of distribution of first light emitting elements in a first display region according to at least one embodiment of the present disclosure.

FIG. 6 is a partial schematic view of the first display region in FIG. 5.

FIG. 7 is a schematic diagram of wirings of a first conductive layer according to at least one embodiment of the present disclosure.

FIG. 8 is a partial enlarged view of a region S1 in FIG. 7.

FIGS. 9 and 10 are schematic diagrams of connection of a part of a plurality of rows of first display units and conductive lines according to at least one embodiment of the present disclosure.

FIG. 11A is a schematic diagram of wirings of a first conductive layer in FIG. 9.

FIG. 11B is a schematic diagram of wirings of a second conductive layer in FIG. 9.

FIG. 12A is a schematic diagram of wirings of a first conductive layer in FIG. 10.

FIG. 12B is a schematic diagram of wirings of a second conductive layer in FIG. 10.

FIG. 13 is a schematic diagram of the display device according to the at least one embodiment of the present disclosure.

### DETAILED DESCRIPTION

The embodiments of the present disclosure will be described below with reference to the drawings in detail. Implementations may be implemented in multiple different forms. Those of ordinary skills in the art may easily understand such a fact that implementations and contents may be transformed into other forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one implementation of the present disclosure is not necessarily limited to the size, and a shape and a size of one or more components in the drawings do not reflect an actual scale. In addition, the accompanying drawings schematically illustrate ideal examples, and an implementation of the present disclosure is not limited to shapes, numerical values, or the like shown in the drawings.

Ordinal numerals “first”, “second”, “third”, etc., in the specification are set not to form limits in numbers but only to avoid confusion between constituent elements. In the present disclosure, “plurality/multiple” represents a quantity of two or more than two.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the constituent elements, not to indicate or imply that involved devices or elements are required to have specific orientations and be structured and operated with the specific orientations but only for ease of description of the present specification, and thus should not be understood as limitations on the present disclosure. The positional relationships between the constituent elements are changed as appropriate according to a direction according to which the constituent elements are described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be a fixed connection, a detachable connection, or an integral connection; it may be a mechanical connection or a connection; it may be a direct connection, an indirect connection through a middleware, or an internal communication inside two elements. Those of ordinary skills in the art may understand meanings of the aforementioned terms in the present disclosure according to situations.

In the specification, “electrical connection” includes connection of constituent elements through an element with a certain electrical action. The “element with a certain electrical action” is not particularly limited as long as electrical signals between the connected constituent elements may be transmitted. Examples of the “element with a certain electrical action” not only include an electrode and a wiring, but also include a switching element such as a transistor, a resistor, an inductor, a capacitor, another element with multiple functions, etc.

In the specification, a transistor refers to an element which at least includes three terminals, i.e., a gate, a drain, and a source. The transistor has a channel region between the drain (drain electrode terminal, drain region, or drain electrode) and the source (source electrode terminal, source region, or source electrode), and a current can flow through the drain, the channel region, and the source. In the specification, the channel region refers to a region through which a current mainly flows.

In the specification, a first electrode may be a drain and a second electrode may be a source, or, a first electrode may be a source and a second electrode may be a drain. In a case that transistors with opposite polarities are used, or in a case that a direction of a current is changed during operation of a circuit, or the like, functions of the “source” and the “drain” are sometimes interchangeable. Therefore, the “source” and the “drain” are interchangeable in the specification. In addition, the gate may also be referred to as a control electrode.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In this specification, a circle, oval, triangle, rectangle, trapezoid, pentagon or hexagon, etc. is not strictly defined, but may be an approximate circle, oval, triangle, rectangle, trapezoid, pentagon or hexagon, etc. Some small deformations due to tolerances may exist, and guiding angles, curved edges and deformations thereof may exist.

A “light transmittance” in the present disclosure refers to an ability of light to pass through a medium, and is a percentage of luminous flux passing through a transparent or translucent body to its incident luminous flux.

In the present disclosure, “about” and “substantially” refer to that a boundary is not defined strictly and a case within a range of process and measurement errors is allowed. In the present disclosure, “substantially the same” refers to a case where numerical values differ by less than 10%.

A display substrate is provided in at least one embodiment of the present disclosure, which includes a base substrate, a circuit structure layer, a light emitting structure layer and a plurality of conductive layers. The base substrate includes a display area including a first display region and a second display region which are not overlapped with each other. The second display region may be located on at least one side of the first display region. The circuit structure layer is located on a side of the base substrate, and includes a plurality of first pixel circuits located in the second display region. The light emitting structure layer is located on a side of the circuit structure layer away from the base substrate, and includes a plurality of first display units located in the first display region. At least one first display unit includes a plurality of first light emitting elements emitting light in different colors. A plurality of conductive layers are located between the circuit structure layer and the light emitting structure layer, and include a plurality of conductive lines. At least one first pixel circuit of the plurality of first pixel circuits is electrically connected to at least one first light emitting element through at least one conductive line. A plurality of conductive lines of at least one conductive layer includes a plurality of first conductive lines and a plurality of second conductive lines. The first conductive lines extend along a first direction, and the second conductive lines at least includes first portions extending along the first direction and second portions extending along the second direction. In the second direction, first portions of the plurality of second conductive lines and the plurality of first conductive lines are alternately disposed. The first direction intersects with the second direction.

In the present disclosure, “A extends along a B direction” means that A may include a main portion and a secondary portion connected to the main portion, the main portion is a line, a line segment, or a strip-shaped body, the main portion extends along the B direction, and a length of the main portion extending along the B direction is greater than a length of the secondary portion extending along another direction. “A extends in in the B direction” in the present disclosure means “the main portion of A extends in the B direction”.

In the display substrate according to the embodiment, lengths of the second portions of the second conductive lines can be reduced by interspersing the first portions of the second conductive lines between the plurality of first conductive lines in at least one conductive layer, thereby reducing length differences between the conductive lines and further optimizing a display effect.

In some exemplary implementations, a plurality of first display units arranged along the first direction are one row of first display units. In a direction from a center to an edge of the first display region along the second direction, quantities of first conductive lines located in a same conductive layer to which a plurality of rows of first display units in the first display region are electrically connected are gradually reduced. First portions of second conductive lines in the conductive layer may be disposed at positions left vacant due to the reduction of the quantities of the first conductive lines. In this example, in a same conductive layer, the first portions of the second conductive lines in the conductive layer may be disposed at positions left vacant due to the reduction of the quantities of the first conductive lines, so that the second conductive lines can be interspersed and arranged in the first conductive line, and the lengths of the second portions of the second conductive lines can be reduced, thereby reducing the lengths of the second conductive lines and optimizing the display effect.

In some exemplary implementations, the quantities of first display units in at least two adjacent rows of first display units may be different in the second direction. In this example, due to different quantities of the first display units in the adjacent rows of the first display units, and quantities of the conductive lines electrically connected to the adjacent first display units are different, the first portions of the second conductive lines may be interspersed between the first conductive lines by arranging the conductive lines, and arrangement space for the conductive lines between the adjacent rows of first display units may be not increased. In this way, a length of a longest conductive line can be reduced.

In some exemplary implementations, in a row of first display units, when adjacent first light emitting elements are electrically connected to different conductive lines located in a same conductive layer, conductive lines electrically connected to the adjacent first light emitting elements may be located on opposite sides of an anode connection electrode electrically connected to the first light emitting elements of the row of first display units in the second direction. In this example, by arranging a plurality of conductive lines in one conductive layer on opposite sides of a row of first display units along the second direction, it is advantageous to reduce the lengths of the conductive lines and reasonably arrange the wiring space.

In some exemplary implementations, the at least one first display unit may include a first light emitting element that emits light in a first color, a first light emitting element that emits light in a second color, and two first light emitting elements that emit light in a third color. For example, the first light emitting element emitting light in the first color and the first light emitting element emitting light in the second color may be arranged in a row along the first direction, and two first light emitting elements emitting light in the third color may be arranged in a row along the first direction, and the two rows of first light emitting elements are misaligned in the second direction. In some examples, the light in the first color may be blue light, the light in the second color may be red light, and the light in the third color may be green light. However, the embodiment is not limited thereto.

In some exemplary implementations, a length of a second portion of a second conductive line along the second direction may be greater than a length of one first display unit along the second direction. In this example, the lengths of the second portions of the second conductive lines can be reduced by adjusting arrangement of the second conductive line.

In some exemplary implementations, the plurality of conductive layers may include a first conductive layer and a second conductive layer provided sequentially along a direction away from the base substrate. However, the embodiment is not limited thereto. For example, the plurality of conductive layers may include more than two conductive layers. In this example, the design of two conductive layers can reduce a production cost.

In some exemplary implementations, the first conductive layer may include a plurality of first conductive lines and a plurality of second conductive lines. The second conductive layer may include a plurality of first conductive lines. In this example, the second conductive line may be arranged in the first conductive layer. However, the embodiment is not limited thereto. For example, the second conductive lines may be disposed in the second conductive layer, or the second conductive lines may be disposed in both the first conductive layer and the second conductive layer.

In some exemplary embodiments, the first display region includes N rows of first display units arranged from the center to the edge of the first display region along the second direction A quantity of first display units included in an i-th row of first display units is greater than or equal to a quantity of first display units included in an (i+1)-th row of first display units, wherein i is an integer greater than 0 and less than N. In some examples, N may be 20. However, the embodiment is not limited thereto.

In some exemplary implementations, a quantity of first conductive lines in the second conductive layer to which the i-th row of first display units are electrically connected may be different from a quantity of first conductive lines in the second conductive layer to which the (i+1)-th row of first display units are electrically connected. A quantity of first conductive lines in the first conductive layer to which the i-th row of first display units are electrically connected may be greater than or equal to a quantity of first conductive lines in the first conductive layer to which the (i+1)-th row of first display units are electrically connected. In some examples, the first conductive lines electrically connected to the (i+1)-th row of first display units occupy less wiring space than the first conductive lines electrically connected to the (i+1)-th row of first display units, and unused wiring space of the (i+1)-th row of the first display units may be used to arrange the second conductive lines, thereby achieving reduction of the lengths of the second conductive lines.

In some exemplary implementations, the i-th row of first display units are electrically connected to the second conductive lines in the first conductive layer, first portions of second conductive lines to which the i-th row of first display units are electrically connected are adjacent to first conductive lines in the first conductive layer to which a j-th row of first display units are electrically connected, wherein j is an integer greater than i and less than or equal to N.

In some exemplary implementations, in the i-th row of first display units, first light emitting elements close to the center of the first display region are electrically connected to first pixel circuits through second conductive lines located in the first conductive layer, and first light emitting elements close to the edge of the first display region are electrically connected to first pixel circuits through first conductive lines located in the first conductive layer. In the j-th row of first display units, first light emitting elements close to the center of the first display region are electrically connected to first pixel circuits through first conductive lines located in the second conductive layer, and first light emitting elements close to the edge of the first display region are electrically connected to first pixel circuits through first conductive lines located in the first conductive layer.

In some exemplary implementations, a material of a plurality of conductive layers may include a transparent conductive material. For example, a material of at least one conductive layer may include indium tin oxide (ITO). However, the embodiment is not limited thereto.

Solutions of the embodiments will be described below through some examples.

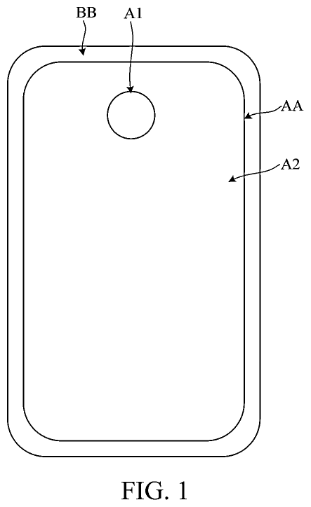

FIG. 1 is a schematic diagram of a display substrate according to at least one embodiment of the present disclosure. In some examples, as shown in FIG. 1, the display substrate may include a display area AA and a peripheral area BB surrounding a periphery of the display area AA. The peripheral region BB may be a non-display area. The display area AA may include a first display region A1 and a second display region A2. For example, a hardware such as a photosensitive sensor (e.g. a camera) is disposed on a side of the display substrate, and an orthographic projection of the photosensitive sensor on the display substrate may be overlapped with the first display region A1. The first display region A1 may be a transparent display region, and the first display region A1 may also be referred to as an Under Display Camera (UDC) region. The second display region A2 may be a normal display region. For example, the second display region A2 may be opaque, but only used for displaying. The display substrate of the present embodiment can be a solid foundation for realization of an all-screen display.

In some examples, as shown in FIG. 1, the first display region A1 may be located at a top central position of the display area AA. The second display region A2 may surround the first display region A1. However, the embodiment is not limited thereto. For example, the first display region A1 may be located at another position such as an upper left corner or an upper right corner of the display area AA. For example, the second display region A2 may surround at least one side of the first display region A1.

In some examples, as shown in FIG. 1, the display area AA may be in a shape of a rectangle, e.g., a rounded rectangle. The first display region A1 may be circular or elliptical. However, the embodiment is not limited thereto. For example, the first display region A1 may be rectangular, semicircular, pentagonal, hexagonal, or have another shape.

In some examples, the display area AA may be provided with a plurality of sub-pixels. At least one sub-pixel may include a pixel circuit and a light emitting element. The pixel circuit is configured to drive a light emitting element to which the pixel circuit is connected. For example, the pixel circuit is configured to provide a drive current to drive the light emitting element to emit light. The pixel circuit may include a plurality of transistors and at least one capacitor. For example, the pixel circuit may be of a 3TIC (i.e., three transistors and one capacitor) structure, a 7TIC (i.e., seven transistors and one capacitor) structure, a 5T1C (i.e., five transistors and one capacitor) structure, an 8TIC (eight transistors and one capacitor) structure, or a 8T2C (eight transistors and two capacitors) structure, or the like.

In some examples, the light emitting element may be any one of a Light Emitting Diode (LED), an Organic Light Emitting Diode (OLED), a Quantum dot Light Emitting Diode (QLED), a Micro LED (including a mini-LED or a micro-LED) and the like. For example, the light emitting element may be an OLED, and the light emitting element may emit red light, green light, blue light, or white light, etc. under drive of a pixel circuit corresponding to the light emitting element. A color of light emitted by the light emitting element may be determined as required. In some examples, the light emitting element may include an anode, a cathode, and an organic light emitting layer located between the anode and the cathode. The anode of the light emitting element may be electrically connected to a corresponding pixel circuit. However, the embodiment is not limited thereto.

In some examples, one display unit of the display area AA may include three sub-pixels, and the three sub-pixels may be a red sub-pixel, a green sub-pixel, and a blue sub-pixel respectively. However, the embodiment is not limited thereto. In some examples, one display unit may include four sub-pixels, and the four sub-pixels may be a red sub-pixel, a green sub-pixel, a blue sub-pixel, and a white sub-pixel respectively.

In some examples, a shape of the light emitting element may be a rectangle, a rhombus, a pentagon, or a hexagon. When one display unit includes three sub-pixels, light emitting elements of the three sub-pixels may be arranged in parallel in a horizontal direction, in parallel in a vertical direction or in a manner to form a triangle. When one display unit includes four sub-pixels, light emitting elements of the four sub-pixels may be arranged in a manner to stand side by side horizontally, in a manner to stand side by side vertically, or in a manner to form a square. However, the embodiment is not limited thereto.

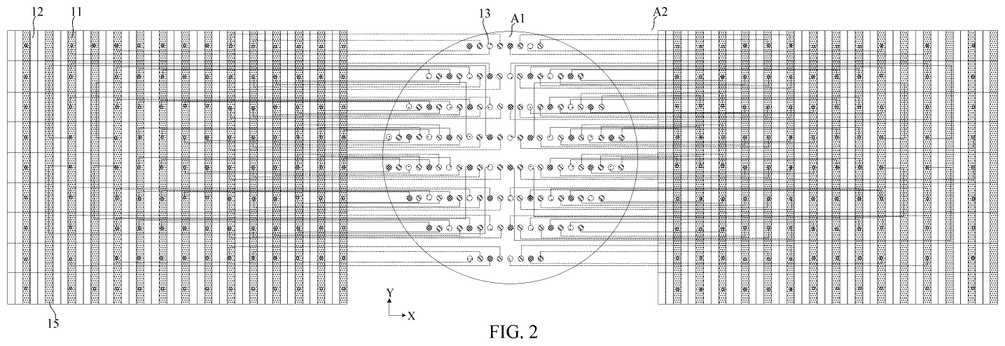

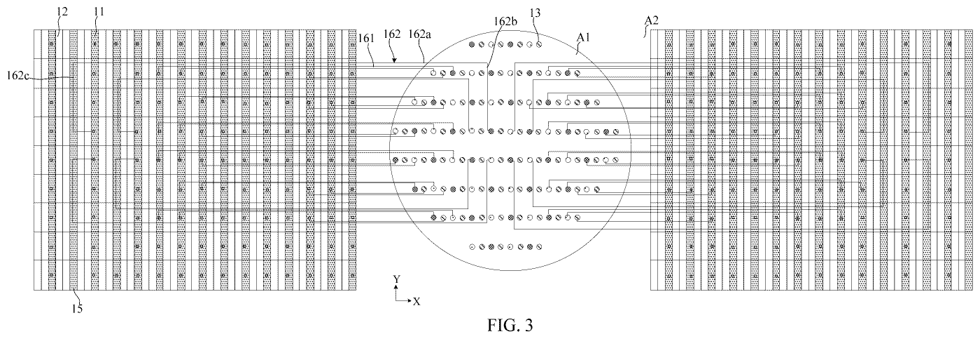

FIG. 2 is a partial schematic view of a display substrate according to at least one embodiment of the present disclosure. FIG. 3 is a schematic diagram of a first conductive layer in FIG. 2. Several rows of first light emitting elements in a first display region A1 are taken as an example for illustration in FIGS. 2 and 3.

In some examples, as shown in FIG. 2, the second display region A2 of the display substrate may include a transition region and a non-transition region. The transition region may be located on at least one side (for example, one side; for another example, all around, i.e., including upper and lower sides and left and right sides) outside the first display region A1. In this example, the transition region may be located on opposite sides of the first display region A1 along a first direction X.

In some examples, as shown in FIG. 2, the first display region A1 may include a plurality of first light emitting elements 13 arranged in an array. The transition region of the second display region may include a plurality of first pixel circuits 11 and a plurality of second pixel circuits 12 arranged in an array, and may further include a plurality of second light emitting elements. At least one second pixel circuit 12 in the transition region may be electrically connected to at least one second light emitting element, and is configured to drive the at least one second light emitting element to emit light. An orthographic projection of the second light emitting element on a base substrate may be at least partially overlapped with an orthographic projection of a second pixel circuit 12 connected to the second light emitting element on the base substrate. At least one first pixel circuit 11 may be electrically connected to at least one first light emitting element 13 disposed within the first display region A1 through a conductive line (e.g., a transparent conductive line), and is configured to drive the at least one first light emitting element 13 to emit light. For example, one end of the conductive line may be electrically connected to the at least one first pixel circuit 11, and the other end of the conductive line may be electrically connected to the at least one first light emitting element 13, and the conductive line may extend from the second display region A2 to the first display region A1. An orthographic projection of a first pixel circuit 11 on the base substrate may be not overlapped with an orthographic projection of the first light emitting element 13 electrically connected to the first pixel circuit 11 on the base substrate. In this example, each first light emitting element 13 in the first display region A1 may be electrically connected to a first pixel circuit 11 in the second display region A2 through at least one conductive line. By disposing the first pixel circuit 11 that drives the first light emitting element 13 in the second display region A2, occlusion of light by the pixel circuit is reduced, thereby increasing a light transmittance of the first display region A1.

In some examples, as shown in FIG. 2, the display substrate may include a first conductive layer and a second conductive layer. The first conductive layer may be located on a side of the second conductive layer close to the base substrate. The first conductive layer includes a plurality of conductive lines represented by solid lines in FIG. 2. The second conductive layer includes a plurality of conductive lines represented by dashed lines in FIG. 2. The first conductive layer and the second conductive layer may be made of a transparent conductive material, for example, may be made of a conductive oxide material, such as Indium Tin Oxide (ITO). However, the embodiment is not limited thereto.

In some examples, as shown in FIG. 2, the non-transition region of the second display region A2 may include a plurality of second pixel circuits 12 and a plurality of invalid pixel circuits 15 arranged in an array, and may further include a plurality of second light emitting elements. At least one second pixel circuit 12 within the non-transition region may be electrically connected to at least one second light emitting element, and an orthographic projection of the at least one second light emitting element on the base substrate may be at least partially overlapped with an orthographic projection of the at least one second pixel circuit 12 electrically connected to the at least one second light emitting element on the base substrate.

In some examples, as shown in FIG. 2, the second display region A2 may further include a plurality of invalid pixel circuits 15. It may be beneficial to improving uniformity of components of a plurality of film layers in an etching process by disposing an invalid pixel circuit. For example, a structure of a invalid pixel circuit may be substantially the same as that of a first pixel circuit and a second pixel circuit of a row or column in which the invalid pixel circuit is located, except that it is not electrically connected to any light emitting element.

In some examples, since the second display region A2 is not only provided with a first pixel circuit 11 electrically connected to a first light emitting element 13, but also provided with a second pixel circuit 12 electrically connected to a second light emitting element, a quantity of pixel circuits of the second display region A2 may be greater than a quantity of second light emitting elements. In some examples, as shown in FIG. 2, a region where newly added pixel circuits (including a first pixel circuit and an invalid pixel circuit) are disposed may be obtained by reducing a dimension of a second pixel circuit 12 in the first direction X. For example, a dimension of a pixel circuit in the first direction X may be smaller than a dimension of a second light emitting element in the first direction X. In this example, as shown in FIG. 2, every a columns of original pixel circuits may be compressed along the first direction X, so that arrangement space of one column of pixel circuits may be newly added, and the space occupied by a columns of pixel circuits before compression and space occupied by a+1 columns of pixel circuits after compression may be the same. Herein, a may be an integer greater than 1. In this example, a may be equal to 2. However, the embodiment is not limited thereto. For example, a may be equal to 3 or 4.

In some other examples, b rows of original pixel circuits may be compressed along a second direction Y, so that arrangement space for one row of pixel circuits is newly added, and space occupied by b rows of pixel circuits before compression and space occupied by b+1 rows of pixel circuits after the compression are the same. Herein, b may be an integer greater than 1. Or, a region in which a newly added pixel circuit is disposed may be obtained by reducing dimensions of a first pixel circuit in the first direction X and the second direction Y.

In an embodiment of the present disclosure, a row of light emitting elements may refer to that pixel circuits connected to the row of light emitting elements are all connected to a same gate line (for example, a scan line). A row of pixel circuits may refer to that the row of pixel circuits are all connected to a same gate line. However, the embodiment is not limited thereto.

In some examples, as shown in FIGS. 2 and 3, a first light emitting element 13 may be electrically connected to a first pixel circuit 11 through a conductive line. In a row of first light emitting elements 13, a first pixel circuit 11 electrically connected to a first light emitting element 13 emitting green light is closer to the first display region A1 than each of first pixel circuits electrically connected to first light emitting elements 13 emitting light in other colors. However, the embodiment is not limited thereto. For example, along the first direction X from a center to an edge of the first display region A1, a first light emitting element 13 close to the center of the first display region A1 may be electrically connected to a first pixel circuit 11 away from the first display region A1, and a first light emitting element 13 away from the center of the first display region A1 may be electrically connected to a first pixel circuit 11 close to the first display region A1.

In some examples, as shown in FIGS. 2 and 3, the first conductive layer of the display substrate may include a plurality of first conductive lines 161 and a plurality of second conductive lines 162. In the second direction Y, the first conductive lines 161 and the second conductive lines 161 are alternately disposed. A first conductive line 161 may be a line with a main portion along the first direction X. A second conductive line 162 may include a first portion 162a extending along the first direction X, and a second portion 162b and a third portion 162c extending along the second direction Y. The first portion 162a is connected between the second portion 162b and the third portion 162c. The second portion 162b may be located in the first display region A1 and electrically connected to a first light emitting element 13 of the first display region A1. The third portion 162c may be located in the second display region A2 and electrically connected to a first pixel circuit 11 of the second display region A2. The first portion 162a may extend from the second display region A2 to the first display region A1. Lengths of the second portion 162b and the third portion 162c may be substantially the same. Lengths of the second portion 162b and the third portion 162c along the second direction Y may be greater than a length of one display unit along the second direction Y. The third portions 162c may be arranged in a region where the invalid pixel circuits 15 are located within the second display region A2. However, the embodiment is not limited thereto.

According to the display substrate provided in this embodiment, in a conductive layer, the first conductive lines may be gradually reduced from the center to the edge of the first display region along the second direction, the second conductive lines may pass through vacant positions between the first conductive lines, such that the lengths of the second portions of the second conductive lines along the second direction can be reduced, thereby reducing a length difference between conductive lines electrically connected to different first light emitting elements, reducing an anode capacitance difference between the first light emitting elements, and further improving a display effect of the display substrate. In some examples, a brightness difference between the first display region and the second display region can be improved by using Double-Gamma Correction, Demura Correction, Image correction (IC) algorithms or the like, which can refer to an existing implementation methods, and is not repeated herein.

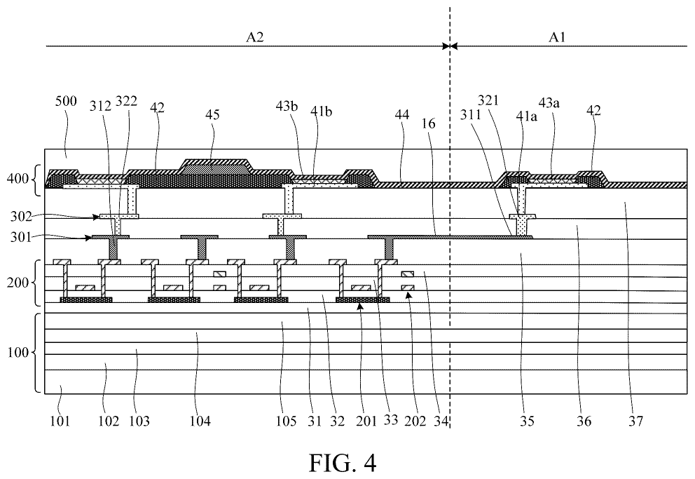

FIG. 4 is a schematic sectional view of a part of a display substrate according to at least one embodiment of the present disclosure. In some examples, as shown in FIG. 4, in a direction perpendicular to the display substrate, a second display region A2 may include a base substrate 100, and a circuit structure layer 200, two conductive layers (e.g. a first conductive layer 301 and a second conductive layer 302), a light emitting structure layer 400, and an encapsulation structure layer 500 which are sequentially disposed on the base substrate 100. In FIG. 4, two conductive layers are taken as an example. The first display region A1 may include the base substrate 100, and a composite insulation layer, two conductive layers (e.g. the first conductive layer 301 and the second conductive layer 302), the light emitting structure layer 400, and the encapsulation structure layer 500 which are sequentially disposed on the base substrate 100. In this example, the first display region A1 may not be provided with the circuit structure layer 200, and a light transmittance of the first display region may be improved.

In some examples, as shown in FIG. 4, the base substrate 100 may include a substrate 101, a first flexible material layer 102, a first inorganic material layer 103, a second flexible material layer 104, and a second inorganic material layer 105 that are stacked sequentially. In some other examples, the first flexible material layer 102 and the first inorganic material layer 103 may be removed from the base substrate 100 of the first display region A1. That is, the base substrate 100 of the first display region may include the substrate 101, the second flexible material layer 104 and the second inorganic material layer 105 stacked sequentially, thereby further facilitating improvement of the light transmittance of the first display region A1.

In some examples, the first flexible material layer 102 and the second flexible material layer 104 may be made of polyimide (PI), polyethylene terephthalate (PET), surface-treated polymer soft film, or other materials, and the first inorganic material layer 103 and the second inorganic material layer 105 may be made of silicon nitride (SiNₓ), silicon oxide (SiOₓ), or other materials, which are configured to improve water and oxygen resistance of the substrate 101. The first inorganic material layer 103 and the second inorganic material layer 105 may be referred to as barrier layers.

In some examples, as shown in FIG. 4, the first display region A1 is not provided with a circuit structure layer. The circuit structure layer 200 of the second display region A2 may include a semiconductor layer, a first gate metal layer, a second gate metal layer, and a first source and drain metal layer which are disposed on the base substrate 100 sequentially. The semiconductor layer may at least include active layers of transistors (e.g. a first transistor 201) of a plurality of pixel circuits. The first gate metal layer may at least include gates of a plurality of transistors (e.g. the first transistor 201) and a first capacitor plate of a storage capacitor (e.g. a first capacitor 202). The second gate metal layer may at least include a second capacitor plate of a storage capacitor (e.g. the first capacitor 202). The first source and drain metal layer may at least include a first electrode and a second electrode of a plurality of transistors (e.g. the first transistors 201). In some examples, the first gate metal layer, the second gate metal layer and the first source and drain metal layer may be made of a metal material, such as any one or more of silver (Ag), copper (Cu), aluminum (Al), titanium (Ti) and molybdenum (Mo), or alloy of the above-mentioned metals, such as aluminum neodymium alloy (AlNd) or molybdenum niobium alloy (MoNb), and may be of a single-layered structure or a multi-layered composite structure, such as Ti/Al/Ti. The semiconductor layer may be made of one or more materials, such as amorphous Indium Gallium Zinc Oxide (a-IGZO), Zinc Oxynitride (ZnON), Indium Zinc Tin Oxide (IZTO), amorphous Silicon (a-Si), polycrystalline Silicon (p-Si), hexathiophene, and polythiophene. That is, the present disclosure is applicable to a transistor manufactured based on an oxide technology, a silicon technology, and an organic matter technology.

In some examples, as shown in FIG. 4, a first insulation layer 31 may be provided between the semiconductor layer and the base substrate 100, a second insulation layer 32 may be provided between the semiconductor layer and the first gate metal layer, a third insulation layer 33 may be provided between the first gate metal layer and the second gate metal layer, and a fourth insulation layer 34 may be provided between the second gate metal layer and the first source and drain layer. In some examples, the first insulation layer 31 may be referred to as a buffer layer, and is configured to improve water and oxygen resistance of the base substrate 100. The second insulation layer 32 and the third insulation layer 33 may be referred to as gate insulation layers. The fourth insulation layer 34 is referred to as an interlayer insulation layer. In some examples, the first insulation layer 31 to the fourth insulation layer 34 may be inorganic insulation layers. For example, the first insulation layer 31, the second insulation layer 32, the third insulation layer 33, and the fourth insulation layer 34 are made of any one or more of Silicon Oxide (SiOₓ), Silicon Nitride (SiNₓ), and Silicon Oxynitride (SiON), and may be a single layer, multiple layers, or a composite layer.

In some examples, as shown in FIG. 4, the first conductive layer 301 of the second display region A2 may at least include a plurality of third anode connection electrodes (e.g. a third anode connection electrodes 312). The second conductive layer 302 of the second display region A2 may at least include a plurality of fourth anode connection electrodes (e.g. a fourth anode connection electrode 322). The fourth anode connection electrode 322 may be electrically connected to the third anode connection electrode 312. The third anode connection electrode 312 may be electrically connected to a second pixel circuit.

In some examples, as shown in FIG. 4, the first conductive layer 301 of the first display region A1 may at least include a plurality of conductive lines 16 and a plurality of first anode connection electrodes (e.g. a first anode connection electrode 311). One end of a conductive line 16 of the first conductive layer 301 and a first anode connection electrode 311 may be of an integral structure, and the other end of the conductive line 16 may extend to the second display region A2 and be electrically connected to a first pixel circuit of the second display region A2. The second conductive layer 302 of the first display region A1 may at least include a plurality of conductive lines and a plurality of second anode connection electrodes (e.g. a second anode connection electrode 321). One end of a conductive line of the second conductive layer 302 and a second anode connection electrode may be of an integral structure, and the other end of the conductive line may extend to the second display region A2 and be electrically connected to a first pixel circuit of the second display region A2. At least one second anode connection electrode 321 of the second conductive layer 302 may be electrically connected to a first anode connection electrode 311 of the first conductive layer 301.

In some examples, as shown in FIG. 4, a fifth insulation layer 35 may be provided between the first conductive layer 301 and the first source and drain metal layer, and a sixth insulation layer 36 may be provided between the first conductive layer 301 and the second conductive layer 302. In some examples, the fifth insulation layer 35 may be an inorganic insulation layer or an organic insulation layer, and the sixth insulation layer 36 may be an organic insulation layer. The first conductive layer 301 and the second conductive layer 302 may be made of a transparent conductive material, such as ITO, IZO, or the like. However, the embodiment is not limited thereto.

In some examples, as shown in FIG. 4, the light emitting structure layer of the first display region A1 may include an anode layer (e.g. an anode layer including an anode 41a of a first light emitting element), a first pixel definition layer 42, an organic light emitting layer (e.g., an organic light emitting layer including an organic light emitting layer 43a of a first light emitting element), and a cathode layer 44. The light emitting structure layer 400 of the second display region A2 may include an anode layer (e.g. an anode layer including an anode 41b of a second light emitting element), the second pixel definition layer 42, an organic light emitting layer (e.g., an organic light emitting layer including an organic light emitting layer 43b a second light emitting element), and the cathode layer 44. For example, the anode 41a of the first light emitting element of the first display region A1 may be electrically connected to a first pixel circuit through the second anode connection electrode 321, a first anode connection electrode 311 and the conductive line 16. An anode 41b of the second light emitting element of the second display region A2 may be electrically connected to a second pixel circuit through a fourth connection electrode 322 and a third connection electrode 312.

In some examples, a seventh insulation layer 37 is provided between the anode layer of the display area and the second conductive layer 302. In some examples, the seventh insulation layer 37 may be an organic insulation layer. The cathode layer of the first display region A1 and the cathode layer of the second display region A2 may be of an integral structure. In this example, the cathode layer of the display area may be a full-surface cathode. However, the embodiment is not limited thereto. For example, the cathode layer of the first display region may be a patterned cathode with a hollowed-out region. For example, the cathode layer may be a transparent cathode, for example, may be made of a transparent conductive material, such as ITO, IZO or the like. In this example, a light emitting element may emit light from a side away from the base substrate through the transparent cathode, thus a top emission structure is achieved.

In some examples, as shown in FIG. 4, the pixel definition layer 42 may have a plurality of pixel openings. The pixel openings may expose a surface of the anode layer. The organic light emitting layer may be in contact with an anode exposed by a pixel opening. For example, the pixel definition layer within the first display region A1 may include a plurality of separated pixel definition blocks, a light transmissive region may exist between adjacent pixel definition blocks, which may provide a light channel for a photosensitive sensor under the first display region (e.g., an under display camera). In some examples, the pixel definition layer may be black. By providing the black pixel definition layer, stray light may be absorbed, diffraction may be reduced and a shooting effect of the under display camera may be optimized. The pixel definition layer 42 of the second display region A2 may be transparent and continuous. In some examples, the pixel definition layer 42 may be made of a material such as polyimide, acrylic, or polyethylene terephthalate.

In some examples, any organic light emitting layer may include a hole injection layer, a hole transport layer, an light emitting layer, an electron transport layer, and an electron injection layer which are stacked. For example, an organic light emitting layer 43b of a second light emitting element is formed in a pixel opening of the pixel definition layer 42 of the second display region A2, and an organic light emitting layer 43a of a first light emitting element is formed in a pixel opening of the pixel definition layer 42 of the first display region A1. An organic light emitting layer may be connected to an anode of a light emitting element.

In some examples, a Post Spacer (PS) layer may be provided on a side of the pixel definition layer 42 away from the base substrate 100, wherein the post spacer layer may include a plurality of first post spacers 45 located in the first display region A1 and a plurality of second post spacers located in the second display region A2. In some examples, a density of the first post spacers of the first display region A1 is less than a density of the second post spacers 45 of the second display region A2.

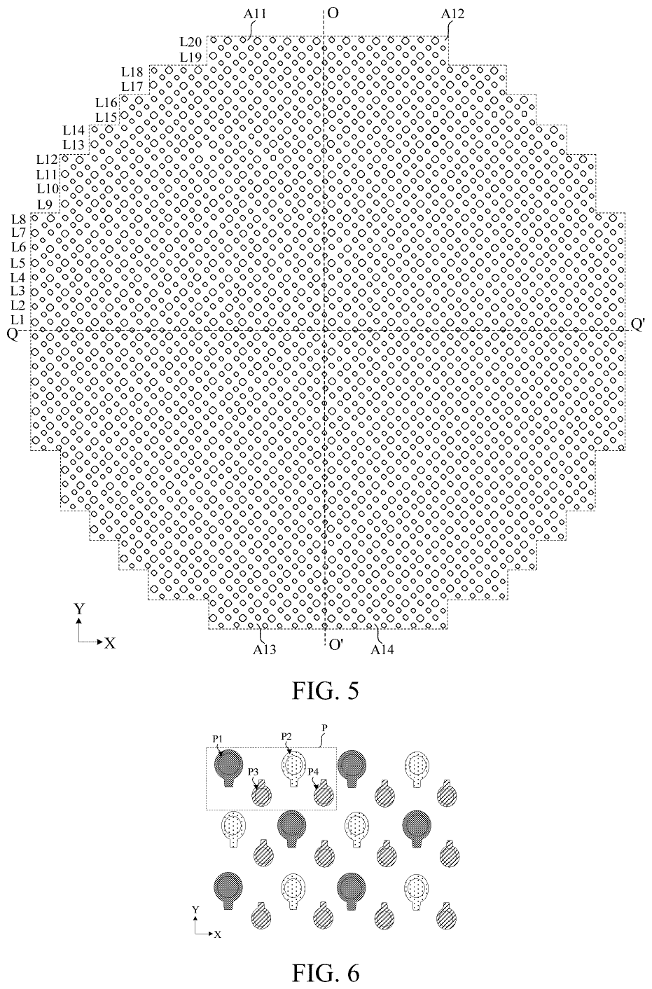

FIG. 5 is a schematic diagram of distribution of first light emitting elements in a first display region according to at least one embodiment of the present disclosure. FIG. 6 is a partial schematic view of the first display region in FIG. 5. In some examples, as shown in FIGS. 5 and 6, the first display region A1 may be substantially circular or elliptical. The first display region A1 may include a plurality of first display units P arranged regularly. The plurality of first display units P may be arranged in a plurality of rows and a plurality of columns. A plurality of first display units P arranged along a first direction X may be referred to as a row of first display units. A plurality of first display units P arranged along a second direction Y may be referred to as a column of first display units. The first direction X may intersect with the second direction Y. For example, the first direction X may be perpendicular to the second direction Y.

In some examples, as shown in FIG. 6, at least one first display unit P may include a first light emitting element P1 that emits light in a first color, a first light emitting element P2 that emits light in a second color, and two first light emitting elements P3 and P4 that emit light in a third color. For example, the light in the first color may be blue light, the light in the second color may be red light, and the light in the third color may be green light. In the first display units P, the first light emitting elements P1 that emit the light in the first color and the first light emitting elements P2 that emit the light in the second color may be sequentially arranged in the first direction X and the second direction Y, respectively. The first light emitting elements P3 and P4 emitting the light in the third color may be sequentially arranged in the first direction X and the second direction Y, respectively. The rows in which the first light emitting elements P1 and P2 are located and the rows in which the first light emitting elements P3 and P4 are located may be arranged at intervals, and may be misaligned in the second direction Y. However, the embodiment is not limited thereto.

In some examples, as shown in FIG. 5, the first display region may have a first centerline OO′ along the first direction X, and a second centerline QQ′ along the second direction Y. The first display region may be divided into four sub-regions by the first centerline OO′ and the second centerline QQ′, e.g. a first sub-region A11, a second sub-region A12, a third sub-region A13, and a fourth sub-region A14. Arrangement of light emitting elements in the four sub-regions may be approximately the same. First light emitting elements in the first sub-region A11 and the third sub-region A13 may be electrically connected to first pixel circuits in a second display region on a left side of a first display region, and first light emitting elements in the second sub-region A12 and the fourth sub-region A14 may be electrically connected to first pixel circuits in a second display region on a right side of the first display region. The first light emitting elements in the first sub-region A11 and the second sub-region A12 may be electrically connected to the first pixel circuits in a manner of being substantially symmetrical with respect to the first centerline OO′, and the first light emitting elements in the third sub-region A13 and the fourth sub-region A14 may be electrically connected to the first pixel circuits in a manner of being substantially symmetrical with respect to the first centerline OO′. The first light emitting elements in the first sub-region A11 and the third sub-region A13 may be electrically connected to the first pixel circuits in a manner of being substantially symmetrical with respect to the second centerline QQ′, and the first light emitting elements in the second sub-region A12 and the fourth sub-region A14 may be electrically connected to the first pixel circuits in a manner of being substantially symmetrical with respect to the second centerline QQ′.

The first sub-region A11 is taken as an example for description below. In some examples, as shown in FIG. 5, the first sub-region A11 may include 20 rows of first display units (i.e., a first row of first display units L1 to a twentieth row of first display units L20), and quantities of first display units within a plurality of rows of first display units gradually decrease in a direction from the second centerline QQ′ to an edge of the first display region along the second direction Y. For example, quantities of the first display units in the first row of first display units L1 to the eighth row of first display units L8 may be approximately the same, e.g. may be about ten. Quantities of the first display units in the ninth row of the first display units L9 to the twelfth row of the first display units L12 may be approximately the same, e.g. may be about nine. Quantities of the first display units in the thirteenth row of first display units L13 and the fourteenth row of first display units L14 may be approximately the same, e.g. about eight. Quantities of the first display units in the fifteenth row of first display units L15 and the sixteenth row of first display units L16 may be approximately the same, e.g. about seven. Quantities of the first display units in the seventeenth row of first display units L17 and the eighteenth row of first display units L18 may be approximately the same, e.g. about six. Quantities of the first display units in the nineteenth row of first display units L19 and twentieth row of first display units L20 may be approximately the same, for example, about five.

In some examples, each first display unit may include four first light emitting elements, and each first light emitting element is electrically connected to the first pixel circuit through one conductive line. For example, each of the first row of first display units L1 to the eighth row of first display units L8 need to be connected to 40 conductive lines, each of the ninth row of first display units L9 to the twelfth row of first display units L12 need to be connected to 36 conductive lines, each of the thirteenth row of first display units L13 and the fourteenth row of first display units L14 need to be connected to 32 conductive lines, each of the fifteenth row of first display units L15 and the sixteenth row of first display units L16 need to be connected to 28 conductive lines, each of the seventeenth row of first display units L17 and the eighteenth row of first display units L18 need to be connected to 24 conductive lines, and each of the nineteenth row of first display units L19 and the twentieth row of first display units L20 need to be connected to 20 conductive lines.

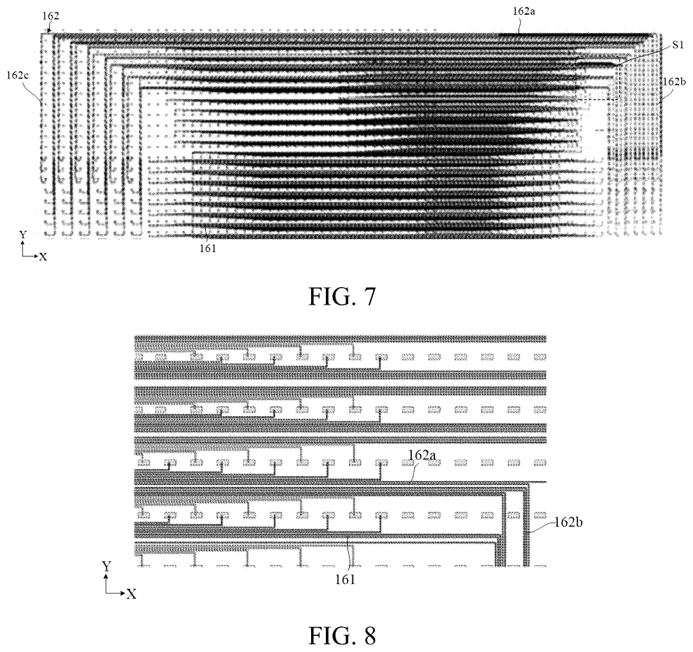

In some examples, two conductive layers are taken as an example. FIG. 7 is a schematic diagram of wirings of a first conductive layer according to at least one embodiment of the present disclosure. FIG. 7 illustrates conductive lines located in the first conductive layer and electrically connected to the first light emitting elements in the first sub-region A11 in FIG. 5. FIG. 8 is a partial enlarged view of an area S1 in FIG. 7.

In some examples, as shown in FIGS. 7 and 8, the first conductive layer may include a first conductive line 161 and a second conductive line 162. In a second direction Y from a center to an edge of a first display region, quantities of first display units in a plurality of rows of first display units within the first sub-region are gradually reduced. Arrangement spaces between each two adjacent rows of first display units are approximately the same. A quantity of first display units in a row of first display units close to the edge of the first display region is reduced, and a quantity of electrically connected first conductive lines 161 is also reduced. A first portion 162a of the second conductive line 162 electrically connected to a row of first display units close to the center of the first display region may be arranged at a position left vacant due to the reduction of the quantities of the first conductive lines 161, thereby reducing a length of a second portion 162b of the second conductive line 162. The second portion 162b of the second conductive line 162 may extend along the second direction Y. Second portions 162b of a plurality of second conductive lines 162 may be disposed adjacent to each other. However, the embodiment is not limited thereto.

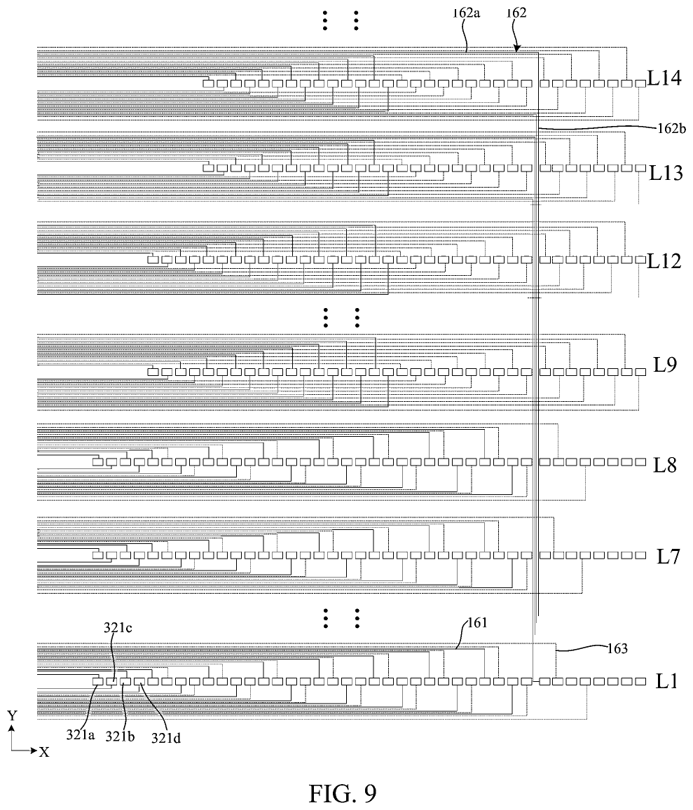

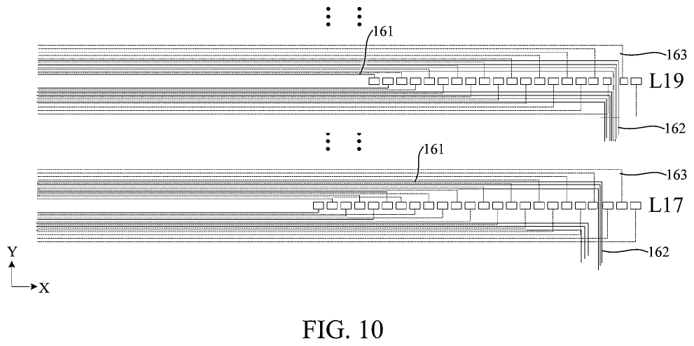

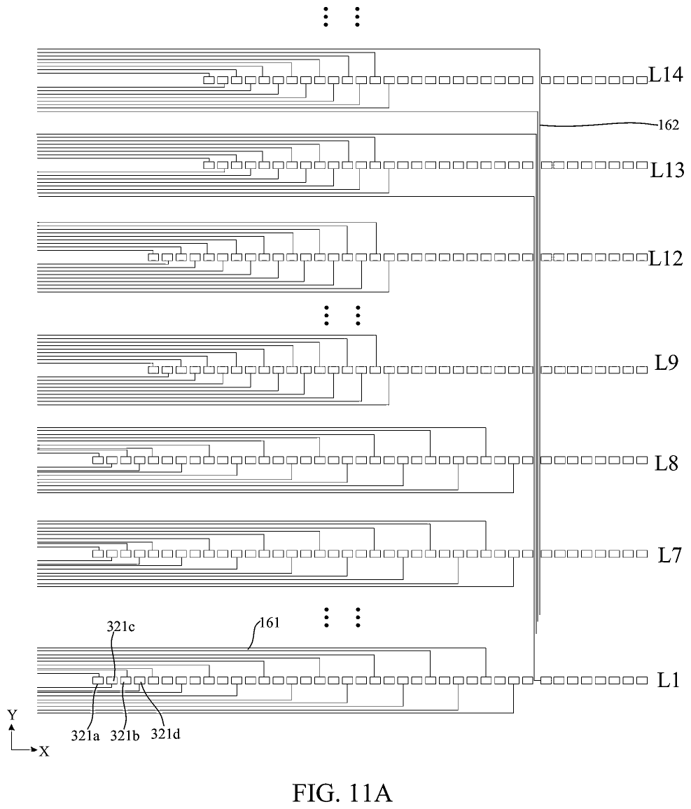

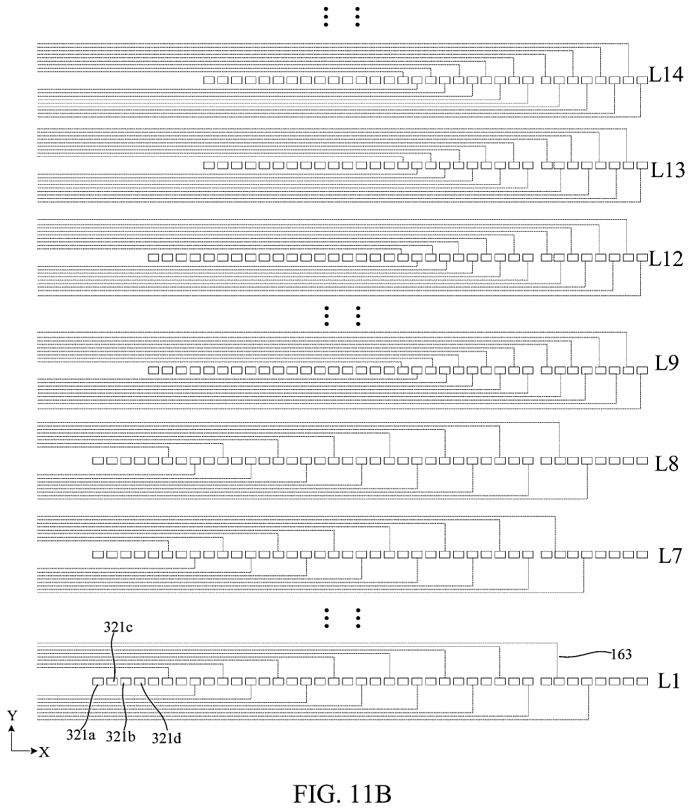

FIGS. 9 and 10 are schematic diagrams of connection of a part of a plurality of rows of first display units and conductive lines according to at least one embodiment of the present disclosure. FIG. 9 is a schematic diagram of connection of a part of a first row of first display units L1 to a fourteenth row of first display units L14. FIG. 10 is a schematic diagram of connection of a part of a seventeenth row of first display units L17 to a nineteenth row of first display units L19. FIG. 11A is a schematic diagram of wirings of a first conductive layer in FIG. 9. FIG. 11B is a schematic diagram of wirings of a second conductive layer in FIG. 9. FIG. 12A is a schematic diagram of wirings of a first conductive layer in FIG. 10. FIG. 12B is a schematic diagram of wirings a wiring diagram of a second conductive layer in FIG. 10.

In some examples, as shown in FIGS. 9 to 12B, a display substrate including a first conductive layer and a second conductive layer which are stacked is taken as an example. The first conductive layer may be located on a side of the second conductive layer close to a base substrate. The first conductive layer may include a plurality of first conductive lines 161 and a plurality of second conductive lines 162, and the second conductive layer may include a plurality of first conductive lines 163. In FIGS. 9 to 12B, solid lines may represent conductive lines in the first conductive layer, and dashed lines may represent conductive lines of the second conductive layer. Only conductive lines in the first display region are illustrated in FIGS. 9 to 12B, and shapes of the conductive lines in the second display region may be similar to shapes of the conductive lines in the first display region. In this example, the second conductive lines may be arranged only in the first conductive layer. However, the embodiment is not limited thereto. In some other examples, the second conductive lines may be arranged in the second conductive layer, or the second conductive lines may be arranged in both the first conductive layer and the second conductive layer.

In some examples, as shown in FIG. 9, both the first conductive lines 161 in the first conductive layer and the first conductive lines 163 in the second conductive layer may extend along a first direction X. Taking a first conductive line 161 as an example, the first conductive line 161 may include a main portion and a secondary portion connected with the main portion. The main portion may extend along the first direction X, and the secondary portion may extend along a second direction Y, and a length of the secondary portion along the second direction Y may be smaller than a length of one first display unit along the second direction Y. The secondary portion of the first conductive line 161 may be electrically connected to a first anode connection electrode located in the first conductive layer, for example, they may be of an integral structure, and then electrically connected to a second anode connection electrode located in the second conductive layer through the first anode connection electrode. The secondary portion of the first conductive line 163 in the second conductive layer may be electrically connected to the second anode connection electrode located in the second conductive layer, for example, they may be of an integral structure. In some examples, orthographic projections of the first anode connection electrode and the second anode connection electrode on the base substrate may be rectangular, such as rounded rectangle. As shown in FIG. 9, a plurality of sets of second anode connection electrodes may be sequentially arranged in the first direction X. One set of second anode connection electrodes may include four second anode connection electrodes 321a to 321d electrically connected to one first display unit. For example, the second anode connection electrode 321a may be electrically connected to an anode of a first light emitting element emitting light in a first color in one first display unit, the second anode connection electrode 321b may be electrically connected to an anode of a first light emitting element emitting light in a third color in the first display unit, the third anode connection electrode 321c may be electrically connected to an anode of a first light emitting element emitting light in a second color in the first display unit, and the fourth anode connection electrode 321d may be electrically connected to an anode of another first light emitting element emitting light in the third color in the first display unit.

In some examples, as shown in FIG. 9, a second conductive line 162 in the first conductive layer may include a first portion 162a extending along the first direction X, and a second portion 162b extending along the second direction Y. The first portion 162a is connected to the second portion 162b. A length of the second portion 162b along the second direction Y may be greater than a length of one display unit along the second direction Y. For example, a length of a first display unit along the second direction Y may be about 57 microns to 71 microns, for example, may be about 64.4 microns.

In some examples, description is made by taking an example in which a quantity of first conductive lines in one conductive layer, which are connected to each row of first display units, is less than or equal to 18. Since the quantities and arrangement of the first display units in the first row of the first display units L1 to the eighth row of the first display units L8 are approximately the same, the first row of first display units L1 is taken as an example for description. The first row of first display units L1 are electrically connected to 18 first conductive lines 161 located in the first conductive layer, and may also be electrically connected to 16 first conductive lines 163 located in the second conductive layer. In some examples, a first light emitting element emitting light in the third color in the first row of first display units L1 may be electrically connected to a first pixel circuit through a first conductive line 161 located in the first conductive layer or a first conductive line 163 located in the second conductive layer. 16 first light emitting elements emitting light in the first color or light in the second color close to the edge of the first display region may be electrically connected to a first pixel circuit through a first conductive line 161 located in the first conductive layer or a first conductive line 163 located in the second conductive layer. For example, 18 first light emitting elements emitting light in the third color in the first row of first display units L1 may be electrically connected to 2 first conductive lines 161 located in the first conductive layer and 16 first conductive lines 163 located in the second conductive layer, respectively, and 2 first light emitting elements emitting light in the third color close to the center of the first display region may be electrically connected to a first pixel circuit through a second conductive line located in the first conductive layer. 16 first light emitting elements emitting light in the first color or light in the second color close to the edge of the first display region may be electrically connected to 16 first conductive lines 161 located in the first conductive layer, respectively. 4 first light emitting elements emitting light in the first color or light in the second color close to the center of the first display region may be electrically connected to a first pixel circuit through a second conductive line located in the first conductive layer. Therefore, the first row of first display units L1 needs to be electrically connected to 6 second conductive lines located in the first conductive layer. The first row of first display units L1 to the eighth row of first display units L8 need 48 second conductive lines located in the first conductive layer in total. In this example, the first row of first display units L1 are electrically connected to 18 first conductive lines 161 located in the first conductive layer, and may also be electrically connected to 16 first conductive lines 163 located in the second conductive layer.

In some examples, as shown in FIGS. 9, 11A and 11B, 36 first light emitting elements of the ninth row of first display units L9 are sequentially numbered in a direction from the edge to the center of the first display region in the first direction X. The nineteenth to the thirty-sixth first light emitting elements of the ninth row of first display units L9 may be electrically connected to first conductive lines 163 located in the second conductive layer, and the first to the eighteenth first light emitting elements of the ninth row of first display units L9 may be electrically connected to first conductive lines 161 located in the first conductive layer. In this example, the ninth row of first display units L9 are electrically connected to 18 first conductive lines located in the first conductive layer, and may also be electrically connected to 18 second conductive lines located in the second conductive layer. First light emitting elements of the tenth row of first display units L10 to the twelfth row of first display units L12 are connected to conductive lines in a manner the same as the connection between the first light emitting elements of the ninth row of first display units L9 to the conductive lines, which is not repeated here.

In some examples, as shown in FIGS. 9, 11A and 11B, 32 first light emitting elements of the thirteenth row of first display units L13 are sequentially numbered in the direction from the edge to the center of the first display region in the first direction X. The fifteenth to the thirty-second first light emitting elements of the thirteenth row of first display units L13 may be electrically connected to first conductive lines 163 located in the second conductive layer, and the first to the fourteenth first light emitting elements of the thirteenth row of first display units L13 may be electrically connected to first conductive lines 161 located in the first conductive layer. The thirteenth row of first display units L13 may be electrically connected to eighteen first conductive lines located in the second conductive layer, and may also be electrically connected to 14 first conductive lines located in the first conductive layer. In this example, the thirteenth row of display units L13 are electrically connected to only 14 first conductive lines located in the first conductive layer. Compared with the first to the twelfth rows of first display units each being electrically connected to 18 first conductive lines located in the first conductive layer, a region where the thirteenth row of display units L13 are located has remained space for arranging 4 first conductive lines in the first conductive layer. First light emitting elements of the fourteenth row of first display units L14 are connected to conductive lines in a manner the same as the connection between first light emitting elements of the thirteenth row of first display units L13 and the conductive lines, which is not repeated here.

In some examples, 28 first light emitting elements of the fifteenth row of first display units L15 are sequentially numbered in the direction from the edge to the center of the first display region in the first direction X. The eleventh to the twenty-eighth first light emitting elements of the fifteenth row of first display units L15 may be electrically connected to first conductive lines 163 located in the second conductive layer, and the first to the tenth first light emitting elements of the fifteenth row of first display units L15 may be electrically connected to first conductive lines 161 located in the first conductive layer. The fifteenth row of first display units L15 may be electrically connected to 18 first conductive lines located in the second conductive layer, and may also be electrically connected to 10 first conductive lines located in the first conductive layer. In this example, the fifteenth row of display units L15 are electrically connected to only 10 first conductive lines located in the first conductive layer. Compared with the first to the twelfth rows of first display units each being electrically connected to 18 first conductive lines located in the first conductive layer, a region where the fifteenth row of display units L15 are located has remained space for arranging 8 first conductive lines in the first conductive layer. First light emitting elements of the sixteenth row of first display units L16 are connected to conductive lines in a manner the same as the connection between first light emitting elements of the fifteenth row of first display units L15 and the conductive lines, which is not repeated here.

In some examples, as shown in FIGS. 10, 12A and 12B, 24 first light emitting elements of the seventeenth row of first display units L17 are sequentially numbered in the direction from the edge to the center of the first display region in the first direction X. The seventh to the twenty-fourth first light emitting elements of the seventeenth row of first display units L17 may be electrically connected to first conductive lines 163 located in the second conductive layer, and the first to the sixth first light emitting elements of the seventeenth row of first display units L15 may be electrically connected to first conductive lines 161 located in the first conductive layer. The seventeenth row of first display units L17 may be electrically connected to 18 first conductive lines located in the second conductive layer, and may also be electrically connected to 6 first conductive lines located in the first conductive layer. In this example, the seventeenth row of display units L17 are electrically connected to only 6 first conductive lines located in the first conductive layer. Compared with the first to the twelfth rows of first display units each being electrically connected to 18 first conductive lines located in the first conductive layer, a region where the seventeenth row of display units L17 are located has remained space for arranging 12 first conductive lines of the first conductive layer. First light emitting elements of the eighteenth row of first display units L18 are connected to conductive lines in a manner the same as the connection between first light emitting elements of the seventeenth row of first display units L17 and the conductive lines, which is not repeated here.

In some examples, as shown in FIGS. 10, 12A and 12B, 20 first light emitting elements of the nineteenth row of first display units L19 are sequentially numbered in the direction from the edge to the center of the first display region in the first direction X. The third to the twentieth first light emitting elements in the nineteenth row of first display units L19 may be electrically connected to first conductive lines 163 located in the second conductive layer, and the first to the second first light emitting elements in the nineteenth row of first display units L19 may be electrically connected to first conductive lines 161 located in the first conductive layer. The nineteenth row of first display units L19 may be electrically connected to 18 first conductive lines located in the second conductive layer, and may also be electrically connected to 2 first conductive lines located in the first conductive layer. In this example, the nineteenth row of display units L19 are electrically connected to only 2 first conductive lines located in the first conductive layer. Compared with the first to the twelfth rows of first display units each being electrically connected to 18 first conductive lines located in the first conductive layer, a region where the nineteenth row of display units L19 are located has space remained for arranging 16 first conductive lines in the first conductive layer. First light emitting elements of the twentieth row of first display units L20 are connected to conductive lines in a manner the same as the connection between first light emitting elements of the nineteenth row of first display units L19 and the conductive lines, which is not repeated here.

In some examples, as shown in FIGS. 9 to 12B, first conductive lines 161 in the first conductive layer to which any row of first display units are electrically connected may be located on opposite sides of the row of first display units in the second direction Y. First conductive lines 163 of the second conductive layer to which any row of first display units are electrically connected may be located on opposite sides of the row of first display units in the second direction Y. In this example, arranging the first conductive lines on opposite sides of the row of first display units in the second direction Y may be beneficial to the arrangement of the first conductive lines, and avoid lengths of secondary portions of the first conductive lines extending in the second direction from being too large.

In some examples, as shown in FIGS. 9 and 11A, the remaining space for 4 first conductive lines in the first conductive layer in the region where the thirteenth row of first display units L13 are located (i.e., the space not occupied by the first conductive lines in the first conductive layer), the remaining space for 4 first conductive lines in the first conductive layer in the region where the fourteenth row of first display units L14 are located, the remaining space for 8 first conductive lines in the region where the fifteenth row of first display units L15 are located, the remaining space for 8 first conductive lines in the region where the sixteenth row of first display units L16 are located, the remaining space for 12 first conductive lines in the region where the seventeenth row of first display units L17 are located, the remaining space for 12 first conductive lines in the region where the eighteenth row of first display units L18 are located, the remaining space for 16 first conductive lines in the region where the nineteen row of first display units L19 are located and the remaining space for 16 first conductive lines in the region where the twentieth row of first display units L20 are located can be used for arranging the second conductive lines.

In some examples, first portions of 48 second conductive lines required for a total of the first row of the first display units L1 to the eighth row of the first display units L8 may be arranged within the remaining space for the first conductive lines. For example, the first portions of the 48 second conductive lines needed by the first row of the first display units L1 to the eighth row of the first display units L8 may successively occupy the remaining space for the 4 first conductive lines in the region where the thirteenth row of the first display units L13 are located, the remaining space for the 4 first conductive lines in the region where the fourteenth row of the first display units L14 are located, the remaining space for the 8 first conductive lines in the region where the fifteenth row of the first display units L15 are located, the remaining space for the 8 first conductive lines in the region where the sixteenth row of the first display units L16 are located, and the remaining space for the 8 first conductive lines in the region where the seventeenth row of the first display units L17 are located. However, the embodiment is not limited thereto. In some other examples, first portions 162a of two second conductive lines 162 electrically connected to the first row of first display units L1 may be arranged within the remaining space for the two first conductive lines in the region where the thirteenth row of the first display units L13 are located. For example, the first portions 162a of the two second conductive lines 162 may be arranged on opposite sides of the thirteenth row of first display units L13 in the second direction Y. First portions 162a of the other two second conductive lines 162 electrically connected to the first row of the first display units L1 may be arranged in the remaining space for the two first conductive lines in the region where the fourteenth row of first display units L14 are located. Similarly, the remaining space for 4 first conductive lines in the region where the fifteenth row of first display units L15 are located, the remaining space for 4 first conductive lines in the region where the sixteenth row of the first display units L16 are located, the remaining space for 6 first conductive lines in the region where the seventeenth row of first display units L17 are located, the remaining space for 6 first conductive lines in the region where the eighteenth row of first display units L18 are located, and the remaining space for 8 first conductive lines in the region where the nineteenth row of first display units L19 are located may be occupied in turn.

In some examples, second portions 162b of a plurality of second conductive lines 162 may be adjacent to each other, or may be spaced apart from the anode connection electrodes in the first direction X. However, the embodiment is not limited thereto.

In some examples, Table 1 illustrates resistance of the 48 second conductive lines in this embodiment and resistance of 48 second conductive lines in a contrast method (in ohm). In the contrast method, in one conductive layer, first conductive lines are centrally arranged in a second direction, and then first portions of the second conductive lines are centrally arranged. In this embodiment, an arrangement mode in which the first portions of the second conductive lines are interspersed between the first conductive lines is employed.

TABLE 1

| Number | This embodiment | Contrast method |
|---|---|---|
| 1 | 4157 | 4327 |
| 2 | 4164 | 4332 |
| 3 | 4163 | 4327 |
| 4 | 4089 | 4265 |
| 5 | 4081 | 4257 |
| 6 | 4038 | 4217 |
| 7 | 4030 | 4209 |
| 8 | 4022 | 4201 |
| 9 | 3985 | 4161 |
| 10 | 3992 | 4166 |
| 11 | 3992 | 4163 |
| 12 | 3924 | 4099 |
| 13 | 3902 | 4091 |
| 14 | 3859 | 4051 |
| 15 | 3851 | 4043 |
| 16 | 3843 | 4036 |
| 17 | 3805 | 3996 |
| 18 | 3812 | 4000 |
| 19 | 3809 | 3995 |
| 20 | 3745 | 3925 |
| 21 | 3723 | 3912 |
| 22 | 3683 | 3875 |
| 23 | 3675 | 3867 |
| 24 | 3667 | 3860 |
| 25 | 3583 | 3820 |
| 26 | 3588 | 3822 |
| 27 | 3585 | 3817 |
| 28 | 3520 | 3756 |
| 29 | 3498 | 3744 |
| 30 | 3461 | 3705 |
| 31 | 3453 | 3702 |
| 32 | 3445 | 3694 |
| 33 | 3361 | 3655 |
| 34 | 3364 | 3655 |
| 35 | 3361 | 3649 |
| 36 | 3296 | 3557 |
| 37 | 3277 | 3545 |
| 38 | 3243 | 3514 |
| 39 | 3235 | 3506 |
| 40 | 3160 | 3498 |
| 41 | 3127 | 3459 |
| 42 | 3126 | 3457 |
| 43 | 3123 | 3452 |
| 44 | 3052 | 3384 |
| 45 | 3043 | 3376 |
| 46 | 2950 | 3349 |
| 47 | 2942 | 3341 |
| 48 | 2881 | 3333 |

According to Table 1, the first portions of the second conductive lines of the display substrate provided in this embodiment can be interspersed between the first conductive lines in the same conductive layer in the second direction, which can effectively reduce the lengths of the second portions of the second conductive lines, thereby reducing the lengths of the second conductive lines, reducing length differences between the second conductive lines, and is beneficial to improving the display effect.

A display device is further provided in at least an embodiment of the present disclosure, which includes the display substrate as described above.

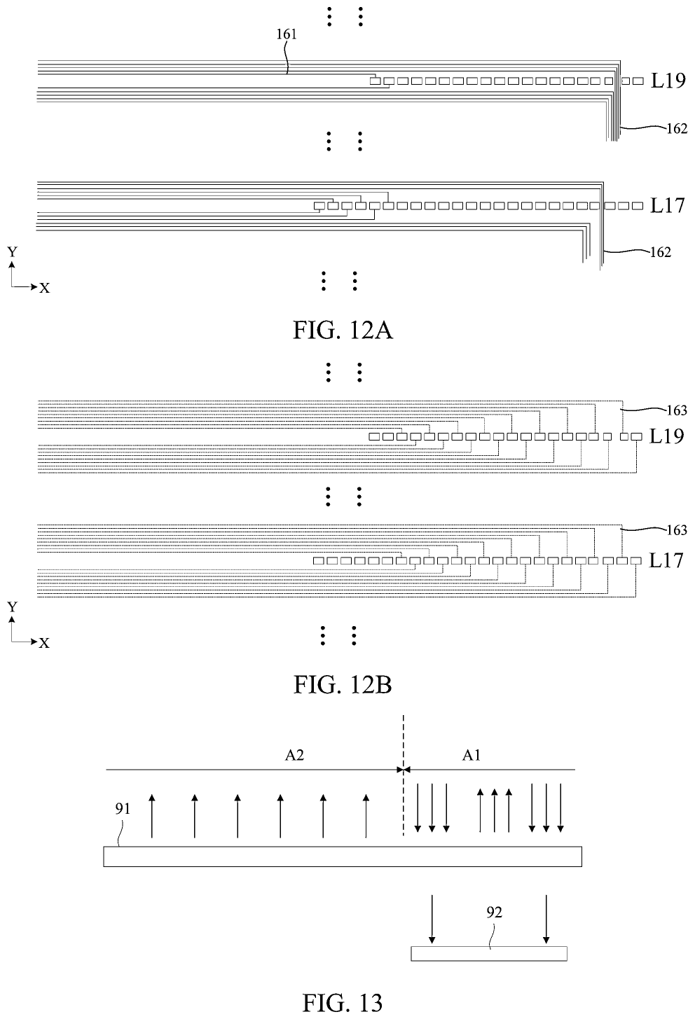

FIG. 13 is a schematic diagram of the display device according to the at least one embodiment of the present disclosure. As shown in FIG. 13, the display device according to the embodiment includes a display substrate 91, and a photosensitive sensor 92 located away from a light emitting side of a display structure layer of the display substrate 91. The photosensitive sensor 92 is located on a side of a non-display surface of the display substrate 91. An orthographic projection of the photosensitive sensor 92 on the display substrate 91 is at least partially overlapped with the first display region A1.

In some exemplary implementations, the display substrate 91 may be a flexible OLED display substrate, a QLED display substrate, a Micro-LED display substrate or a Mini-LED display substrate. The display device may be a product having an image (including a still image or a dynamic image, wherein the dynamic image may be a video) display function. For example, the display device may be: displays, televisions, billboards, digital photo frames, laser printers with display function, telephones, mobile phones, picture screens, personal digital assistants (PDA), digital cameras, portable camcorders, viewfinders, navigators, vehicles, large-area walls, information inquiry equipment (such as business inquiry equipment in e-government, banks, hospitals, power departments, etc.), monitors, etc. As another example, the display device may be any one of a micro-display, a VR device including a micro-display, or an AR device.

The drawings of the present disclosure only involve structures involved in the present disclosure, and other structures may refer to conventional designs. The embodiments of the present disclosure, i.e., features in the embodiments, may be combined with each other to obtain new embodiments if there is no conflict. Those of ordinary skills in the art should understand that modifications or equivalent replacements may be made to the technical solutions of the present disclosure without departing from the essence and scope of the technical solutions of the present disclosure, and shall all fall within the scope of the claims of the present disclosure.

1. A display substrate, comprising:
a base substrate comprising a display area comprising a first display region and a second display region not overlapped with each other, wherein the second display region is located on at least one side of the first display region;
a circuit structure layer located on a side of the base substrate, and comprises a plurality of first pixel circuits located in the second display region;
a light emitting structure layer located on a side of the circuit structure layer away from the base substrate, and comprises a plurality of first display units located in the first display region, wherein at least one of the plurality of first display units comprises a plurality of first light emitting elements emitting light in different colors;
a plurality of conductive layers located between the circuit structure layer and the light emitting structure layer, and comprise a plurality of conductive lines; wherein at least one of the plurality of first pixel circuits is electrically connected to at least one first light emitting element through at least one conductive line, and the at least one first pixel circuit is configured to drive the at least one first light emitting element to emit light; and
a plurality of conductive lines in at least one of the plurality of conductive layers comprise a plurality of first conductive lines and a plurality of second conductive lines; wherein the first conductive lines extend along a first direction, and the second conductive lines at least comprise first portions extending along the first direction and second portions extending along the second direction; in the second direction, the first portions of the plurality of second conductive lines and the plurality of first conductive lines are alternately disposed; and the first direction intersects with the second direction.

2. The display substrate of claim 1, wherein a plurality of first display units arranged along the first direction are one row of first display units; in a direction from a center to an edge of the first display region along the second direction, quantities of the first conductive lines located in a same conductive layer to which a plurality of rows of first display units in the first display region are electrically connected are gradually reduced; the first portions of the second conductive lines in the conductive layer are disposed at positions left vacant due to the reduced quantities of the first conductive lines.

3. The display substrate of claim 2, wherein quantities of first display units in at least two adjacent rows of first display units are different in the second direction.

4. The display substrate of claim 2, wherein, in a row of first display units, when adjacent first light emitting elements are electrically connected to different conductive lines located in the same conductive layer, the conductive lines electrically connected to the adjacent first light emitting elements are located on opposite sides of anode connection electrodes electrically connected to the first light emitting elements of the row of first display units in the second direction.

5. The display substrate of claim 1, wherein a length of a second portion of the second conductive line along the second direction is greater than a length of one first display unit along the second direction.

6. The display substrate of claim 1, wherein the at least one first display unit comprises a first light emitting element that emits light in a first color, a first light emitting element that emits light in a second color, and two first light emitting elements that emit light in a third color.

7. The display substrate of claim 1, wherein the plurality of conductive layers comprise a first conductive layer and a second conductive layer provided sequentially along a direction away from the base substrate.

8. The display substrate of claim 7, wherein the first conductive layer comprises a plurality of first conductive lines and a plurality of second conductive lines, and the second conductive layer comprises a plurality of first conductive lines.

9. The display substrate of claim 8, wherein the first display region comprises N rows of first display units arranged from a center to an edge of the first display region along the second direction, wherein a quantity of first display units comprised in an i-th row of first display units is greater than or equal to a quantity of first display units comprised in an (i+1)-th row of first display units, wherein i is an integer greater than 0 and less than N.

10. The display substrate of claim 9, wherein a quantity of first conductive lines in the second conductive layer to which the i-th row of first display units are electrically connected is the same as a quantity of first conductive lines in the second conductive layer to which the (i+1)-th row of first display units are electrically connected; and
a quantity of first conductive lines in the first conductive layer to which the i-th row of first display units are electrically connected is greater than or equal to a quantity of first conductive lines in the first conductive layer to which the (i+1)-th row of first display units are electrically connected.

11. The display substrate of claim 10, wherein the i-th row of first display units are electrically connected to second conductive lines in the first conductive layer, first portions of the second conductive lines to which the i-th row of first display units are electrically connected are adjacent to first conductive lines in the first conductive layer to which a j-th row of first display units are electrically connected, and j is an integer greater than i and less than or equal to N.

12. The display substrate of claim 11, wherein in the i-th row of first display units, first light emitting elements close to the center of the first display region are electrically connected to first pixel circuits through second conductive lines located in the first conductive layer, and first light emitting elements close to the edge of the first display region are electrically connected to first pixel circuits through first conductive lines located in the first conductive layer; and
in the j-th row of first display units, first light emitting elements close to the center of the first display region are electrically connected to first pixel circuits through first conductive lines located in the second conductive layer, and first light emitting elements close to the edge of the first display region are electrically connected to first pixel circuits through first conductive lines located in the first conductive layer.

13. The display substrate of claim 1, wherein the circuit structure layer further comprises a plurality of second pixel circuits located in the second display region;
the light emitting structure layer further comprises a plurality of second light emitting elements located in the second display region; and
at least one of the plurality of second pixel circuits is electrically connected to at least one of the plurality of second light emitting elements, and the at least one second pixel circuit is configured to drive the at least one second light emitting element to emit light.

14. A display device, comprising the display substrate of claim 1.

15. The display device of claim 14, further comprising a photosensitive sensor located on a side of a non-display surface of the display substrate, wherein an orthographic projection of the photosensitive sensor on the display substrate is at least partially overlapped with the first display region of the display substrate.

16. The display substrate of claim 2, wherein a length of a second portion of the second conductive line along the second direction is greater than a length of one first display unit along the second direction.

17. The display substrate of claim 3, wherein a length of a second portion of the second conductive line along the second direction is greater than a length of one first display unit along the second direction.

18. The display substrate of claim 4, wherein a length of a second portion of the second conductive line along the second direction is greater than a length of one first display unit along the second direction.

19. The display substrate of claim 2, wherein the at least one first display unit comprises a first light emitting element that emits light in a first color, a first light emitting element that emits light in a second color, and two first light emitting elements that emit light in a third color.

20. The display substrate of claim 3, wherein the at least one first display unit comprises a first light emitting element that emits light in a first color, a first light emitting element that emits light in a second color, and two first light emitting elements that emit light in a third color.
